(19) United States
(12) Patent Application Publication
(10) Pub. No.: US 2016/0054381 A1
(43) Pub. Date: Feb. 25, 2016

(54) FUNCTIONAL ELECTRONICS MODULE, OPERATING METHOD FOR A FUNCTIONAL ELECTRONICS MODULE AND SYSTEM HAVING A FUNCTIONAL ELECTRONICS MODULE

(71) Applicant: Weidmüller Interface GmbH & Co. KG, Detmold (DE)

(72) Inventors: Gunter Wakan, Helbra (DE); Sascha Dreifert, Paderborn (DE)

(21) Appl. No.: 14/781,463

(22) PCT Filed: Apr. 7, 2014
(86) PCT No.: PCT/EP2014/056949

§ 371 Date: Sep. 30, 2015

(30) Foreign Application Priority Data
Apr. 5, 2013 (DE) 20 2013 101 455.9

(51) Int. Cl. G01R 31/28

(52) U.S. Cl. CPC G01R 31/2849

(57) ABSTRACT

An operating method is provided for a functional electronics module for autonomous signal processing. The module is suitable for assembly on a mounting rail and has at least one input and/or at least one output. According to the method, a signal is received at the at least one input and the signal is autonomously processed. A signal is emitted to the output. The signal received at the input and/or emitted at the output is detected and emitted in digital form via a first interface via a communication module of the functional electronics module. A service life of a system component is determined based on the signal received at the input and/or emitted at the output. The service life may also be determined based on measured operating parameters of the functional electronics module A functional electronics module suitable for carrying out the method and a system including at least one such functional electronics module and one gateway are also provided.

### REFERENCE TO RELATED APPLICATIONS

This application is a national stage application under 35 C.F.R. §371 of the PCT International Application No. PCT PCT/EP2014/056949 filed Apr. 7, 2014, which claims priority of the German Application No. DE 20 3013 101 455.9 filed Apr. 5, 2013. The entire content of these applications is incorporated herein by reference.

### BACKGROUND OF THE INVENTION

The invention relates to a functional electronics module for assembling on a mounting rail, with at least one input and/or at least one output. The functional electronics module is set up in order to autonomously process a signal applied at the input and/or in order to autonomously emit a signal at the output. The functional electronics module includes a communication module which is set up in order to detect signals applied at the input and/or emitted at the output and to emit them in digital form via a first interface. The invention moreover relates to an operating method for such a functional electronics module and to a system with at least one functional electronics module.

Functional electronics modules are usually used in switch cabinets and can be designed, for example, as measurement signal converters (also referred to as signal converters), as current surge or voltage surge protection devices, as relay or opto-coupler modules and/or as current supply units. The functional electronics modules differ from modules that work in connection with a central automation controller in that they perform their function independently of a higher-level control apparatus.

For example, in a functional electronics module designed as a signal converter, processing of signals applied at the input occurs internally in the functional electronics module and leads to emission at the output without participation of a higher-level automation controller.

In the context of the application, a signal is understood here to mean both low-voltage and also current signals, which are usually used for measurement and control purposes and which are, for example, in the range from 0 to 10 V (Volt) or in the range from 4 to 20 mA (milliamp). Such signals are applied, for example, at voltage, current, temperature, resistance and measurement bridge inputs. In the same way, the term signals is understood to mean power-transmitting currents. A signal converter that processes small signals in this sense is also a functional electronics module such as, for example, a voltage surge protector, in which, at inputs and outputs, a power transmitting alternating current, for example, a mains voltage, is applied. After detection of a voltage surge, this voltage surge is diverted or limited.

The autonomous mode of operation of the functional electronics modules allows a robust interference-resistant operation of a system provided with these modules. The integrated communication module provides signals processed by the functional electronics module in digital form for monitoring and maintenance purposes, as a result of which, for example, a monitoring of input/output values (low-voltage signals and also current signals and power-transmitting supply voltages as well as supply currents) and the correct functioning of the functional electronics module or optionally a setting of operating parameters can be automated with little expenditure or carried out by remote maintenance. Functional monitoring can minimize downtime of an installation in the case of a failure of an installation component, since there is no time-intensive searching for a defect. However, failure itself cannot be prevented.

Therefore, a problem to be solved by the invention is to provide a functional electronics module, an operating method for a functional electronics module, and a system with a functional electronics module, in which failures of an installation in which the functional electronics module is used are prevented to the extent possible.

### SUMMARY OF THE INVENTION

An operating method for a functional electronics module for autonomous signal processing which is suitable for assembly on a mounting rail and which has at least one input and/or at least one output is characterized by the following steps. A signal is received at the at least one input, processed autonomously and emitted at the at least one output. The signal applied at the input and/or emitted at the output is emitted in digital form via a first interface by a communication module of the functional electronics module. Then, a service life of an installation component is determined based on the signal applied at the input and/or emitted at the output and/or based on measured operating parameters of the functional electronics module. The installation components whose service life is determined can be the functional electronics module itself and/or an apparatus connected to the input or the output of the functional electronics module.

In this manner, information available to the functional electronics module can be used in order to determine a still expected service life of an installation component—of the functional electronics module itself or a connected apparatus. If there are signs of an imminent end of the service life, a warning message is emitted, after which the installation component can be replaced before there is a defect that would lead to a failure of the installation. In particular, in the case of a functional electronics module that has the communication capacity mentioned at the start, this valuable additional functionality can be implemented without great additional expenditure, since measurement and digitization—necessary for the service life determination—of the signals applied at the input and/or emitted at the output and/or of other operating parameters are already provided.

In a preferred method, the determination of the service life occurs in the functional electronics module itself. Alternatively, the detected information can be transmitted via the processed signals via the first interface to a higher-level gateway, after which the service life is determined within the gateway. An advantage here is that, in the gateway, different information from different functional electronics modules can be combined and this information can enter together into the determination of the service life.

In another embodiment of the method, for the determination of the service life, the signal applied at the input and/or emitted at the output, or an absolute value of a change of one of these signals, can be integrated, wherein, from the value of the integral, wear that has occurred, and thus the service life of the installation component, is determined. Moreover, for the determination of the service life, an absolute and/or relative change of the signal applied at the input and/or of the signal emitted at the output can be considered. Depending on the apparatus that is connected, either the signal itself, for example, a current flow, or also its change, can be a crucial factor for the wear of the apparatus and also of the functional electronics module itself. In the case of functional electronics modules designed as current supply units, for example, the current flow at the output is a measure of both the wear of the components of the functional electronics module itself and also for connected apparatuses.

A functional electronics module according to the invention is set up in order to detect signals applied at the input and/or emitted at the output and/or measured operating parameters of the functional electronics module for the determination of a service life of the functional electronics module and/or an apparatus connected to the input or the output. This results in the advantages mentioned in connection with the method.

In a preferred embodiment of the functional electronics module, the operating parameters include a temperature measured within the functional electronics module and/or a voltage measured within the functional electronics module and/or a current flow within the functional electronics module. Preferably, the operating parameters of the functional electronics module are also emitted in digital form via the first interface. In an advantageous design of the functional electronics module, the first interface is bus capable and in particular is a CAN (Controller Area Network) bus interface. In this manner, multiple functional electronics modules can be connected to one another by a bus system, as a result of which the additional installation expenditure required for the communication capability of the functional electronics module can be kept as small as possible.

In another embodiment, the functional electronics module is designed as a signal converter, wherein a signal applied at the input is represented at the output. Also advantageous is a functional electronics module designed as a current supply unit in which, at the output, a low voltage is provided for the current supply of the components of a switch cabinet.

For the determination of the service life, in the case of a functional electronics module designed as signal converter, a signal emitted at the output or an absolute value of a signal change can be integrated wherein, from the value of the integral, wear that has occurred, and thus the service life of the connected apparatus, is determined. In a functional electronics module designed as a current supply unit, a current flow at the output can be integrated wherein, from the value of the integral, wear that has occurred and thus the service life of the functional electronics module or of the connected apparatus are determined. Alternatively or additionally, it is possible to determine, on the basis of operating parameters of the functional electronics module, a capacitance and/or a series resistance of a smoothing capacitor of the current supply unit and to determine the service life of the current supply unit on the basis of the capacitance and/or the series resistance.

A system according to the invention includes at least one such functional electronics module and a gateway which has a first interface that is connected to the first interface of the communication module. The gateway is set up in order to determine, from the data transmitted by the functional electronics module, the service life of the functional electronics module and/or of an apparatus connected to the input and/or output of the functional electronics module. With the system, the result is the advantage described above in connection with the method and the functional electronics module, namely using information available to the functional electronics module not only for signal processing but also for service life determination, as a result of which the reliability of the installation is increased. An additional advantage of the evaluation of the information in the gateway is that an evaluation can occur at a higher level for multiple functional electronics modules, as a result of which there is no additional computation and/or memory needed in the case of the individual functional electronics module.

In an advantageous design, the system includes multiple functional electronics modules connected to the gateway, wherein the gateway is set up in order to receive data from the multiple functional electronics modules, combine them with one another and determine from this the service life of the apparatus. Here, the resulting additional advantage is that it is possible to combine different information from different functional electronics modules and be able to allow this information to enter together into the determination of the service life.

In another advantageous design of the system, the gateway has a second interface for the connection of a network line for connection to a higher-level data network, in particular an Ethernet. In this manner, warning or diagnostic messages of the gateway can be emitted simply in a control station.

The gateway comprises a separate housing for assembly on a mounting rail so that it can be arranged together with the functional electronics modules in a switch cabinet or the like of the installation. Alternatively, the gateway can also be integrated in a functional electronics module, wherein a connection occurs via internal first interfaces. Preferably, such an integrated gateway also includes a bus-capable first interface for connection to other functional electronics modules.

### BRIEF DESCRIPTION OF THE FIGURES

The invention will be explained in greater detail below when viewed in the light of the accompanying drawing, in which:

FIGS. 1 to 3 each show a representation of a switch cabinet, respectively, with a plurality of functional electronics modules;

FIG. 4 shows a schematic block diagram of a functional electronics module in a first embodiment;

FIG. 5 shows a measured current course at an output of a functional electronics module for the explanation of a useful life determination;

FIG. 6 shows a schematic block diagram of a functional electronics module in a second embodiment;

FIG. 7 shows a schematic functional block diagram of an analysis unit of a functional electronics module; and

FIG. 8 shows a schematic block diagram of a gateway in a first embodiment.

### DETAILED DESCRIPTION

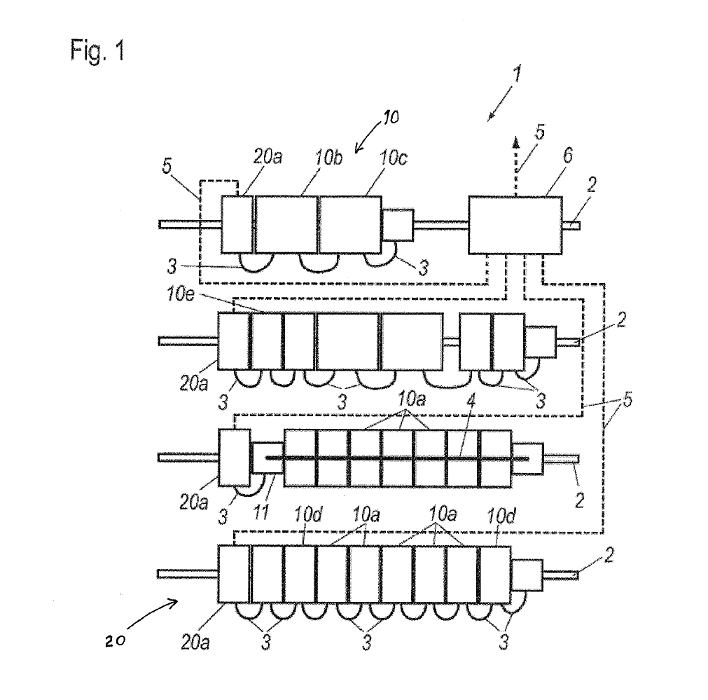

In FIG. 1 a construction example of a switch cabinet 1 is shown in which a plurality of functional electronics modules 10 are arranged on different mounting rails 2.

For the sake of simplicity, only some of the functional electronics modules 10 are provided with reference numerals. The functional electronics modules 10 can provide different functions within the switch cabinet 1. For example, as functional electronics modules 10 in the switch cabinet 1, signal converters 10a can be used and so can current supply units 10b, uninterruptible current supply units 10c, voltage surge modules 10d and current surge protection devices 10e. This list is merely an example and not comprehensive. In the context of the application, the design of functional electronics modules according to the invention explained below can be applied to other types of known functional electronics modules used in the switch cabinet technology. However, all of the functional electronics modules 10 used are characterized in that they can perform their function within the switch cabinet 1 autonomously and independently of a higher-level controller.

For the sake of simplicity, current-carrying cables that lead to the functional electronics modules 10 or to other components of the switch cabinet 1 or that connect these components to one another are not represented. Similarly, cables that are led, for example, from the current supply unit 10b or from the uninterruptible current supply units 10c to other functional electronics modules 10 are not represented.

Multiple functional electronics modules 10 are each connected via a local bus 3 to a gateway 20 also assembled on the mounting rail 2 and, in the example, the gateway is designed as a single gateway 20a which has only one connection for the local bus 3. In the represented example, in each case one of these single gateways 20a is provided per mounting rail 2. This allocation of the functional electronics modules each to a single gateway 20a located on the same mounting rail 2 is not mandatory. The local bus 3 could naturally also lead across to another mounting rail 2.

In the present case, the local bus 3 is looped as a wired bus from one functional electronics module to the respective adjacent functional electronics module 10 and finally to the connection of the respective single gateway 20a.

In principle, other transmission paths for the local bus are also possible. An example is shown in the second mounting rail 2 from the bottom. In this mounting rail 2, the wired local bus 3 is coupled through a feed unit 11 to corresponding bus lines 4 in the mounting rail 2. Advantageously, in addition to the represented bus lines 4, a current supply for the functional electronic modules 10 can also occur via corresponding lines or conducting paths arranged in the mounting rail 2.

The functional electronics modules 10 are each provided with a communication module connected via a first interface to the local bus 3. Via the communication module and the first interface, information can be transmitted from the functional electronics modules 10 to the gateway 20. The gateway 20 transmits this information to a second interface connected via a network line 5, preferably an Ethernet line, to a network switch 6 operating as a distributor. The switch 6 is then connected via another network line 5 to a higher-level data network.

Information emitted by the functional electronics modules 10 is thus available, with little additional expenditure, in the higher-level data network for evaluation and/or recording and/or monitoring. This is possible without requiring fundamental changes to the wiring, the construction and/or the mode of operation of the switch cabinet 1. In particular, the switch cabinet 1 operates autonomously as before and is not dependent on the presence and correct operation of a higher level control apparatus, for example, an automation controller.

In FIG. 2, similar to FIG. 1, another example of a switch cabinet 1 with a plurality of functional electronics modules 10 (10a, 10b, 10c, 10d, 10e) is represented. Again, the functional electronics modules 10 comprise first interfaces which are connected via a wired local bus 3 or via bus lines 4 integrated in the wire rail 2 via gateways 20 to a network line 5 and thus to a higher-level data network.

In contrast to the embodiment of FIG. 1, in the present case, only one gateway 20 is provided, which is designed as multiple gateway 20b. The functional electronics modules 10 are looped via several strings of the local bus 3 each to one of a plurality, in this case four, of connections of the multiple gateway 20b. The multiple gateway 20b combines the functions of the single gateway 20a and the switch 6, as a result of which the additional wiring and assembly expenditure is further reduced.

In FIG. 3, again similar to FIG. 1, another example of a switch cabinet 1 with a plurality of functional electronics modules 10 is represented.

As in the gateway 20 represented in FIG. 1, in the present case, multiple gateways 20, one for each mounting rail 2, are provided. However, the gateways are designed as chained gateways 20c in this embodiment. Each chained gateway 20c includes two second interfaces for a network line 5, wherein the chained gateways 20c are connected to one another in a kind of chain (such as a daisy chain). When using a packet-oriented network as a higher-level data network, for example the Ethernet, this becomes possible because each of the chained gateways 20c includes a dual network switch by which information is either supplied for processing to the other components of the chained gateway 20c itself or led via the second connection for transfer to a succeeding gateway 20.

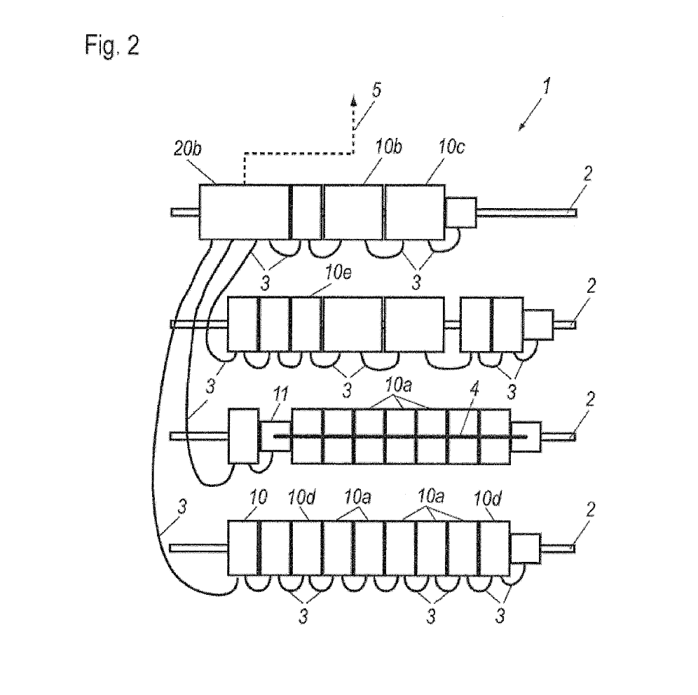

In FIG. 4, the construction of a signal converter 10a is represented in greater detail in the form of a block diagram, as an example of a functional electronics module 10. The functional electronics module 10 can be divided into two component groups, a functional unit 110 and a communication module 120. The functional unit 110 takes over the functions necessary for autonomous signal and current processing. In the present signal converter 10a, the functional unit 110 includes an input 111 designed, for example, as a voltage signal input for an input voltage range from 0 to 10 V. The input 111 is connected to an analog/digital (A/D) converter 112 which converts the voltage signal applied at the input 111 into a digital signal which is emitted onto a digital transmission section 113.

Via this digital transmission section 113, the A/D converter 112 is connected to a digital/analog (D/A) converter 114 which applies an analog signal at an output 115 of the functional electronic module 10. This can be, for example, an analog current signal with a value range from 4 to 20 mA. A conversion of the analog low-voltage signal at the input 111 into an analog output current signal at the output 115 occurs in the represented functional unit 110, that is to say, via the indirect route of the digital transmission section 113. The digital transmission section 113 includes galvanically separating elements, for example, opto-couplers. In this manner, a complete galvanic and reactionless separation between the input 111 and the output 115 is ensured.

The digital transmission section 113 is connected to an input of a microcontroller 121 within the communication module 120. The microcontroller 121 is set up for processing data transmitted on the digital transmission section 113, and evaluating and storing the data temporarily. For the latter purpose, an optional external memory 122 is connected to the microcontroller 121.

The communication module 120 comprises a first interface 123 through which the information is exchanged with a gateway 20 (see FIGS. 1, 2). The first interface 123 is provided in different designs. In the first design, the interface 123 is designed as an internal interface 123a. As explained in further detail below, the internal first interface 123a is provided for internal connection to an integrated gateway 20. In a second design, the interface 123 is designed as a bus-capable interface 123b in the form of a CAN bus, for example. In this design, a connection to an external lead local bus 3, 4 is provided for the connection to a separately implemented gateway 20, as represented in the embodiments of FIGS. 1 and 2.

Moreover, a maintenance interface 124, also referred to as service interface 124, may be provided on the communication module 120. Via the service interface 124, it is possible to set the internal settings of the microcontroller 121 or the programs executed by it and also to update these programs. The service interface 124 can be designed as a USB interface to which a laptop of a service technician can be connected on site at the switch cabinet 1.

Via the first interface 123, the data transmitted on the digital transmission section 113 can be read by the gateway 20 and seen in the high-level network to which the gateway 20 is connected. Thus, recording and/or monitoring of the signals processed by the functional unit 110 of the functional electronics module 10 can occur. In an alternative design, it is possible to provide, between the output of the A/D converter 112 and the input of the D/A converter 114, a programmable recalculation unit within the digital transmission section 113. The recomputing unit makes it possible to modify the functional relationship existing between the input 111 and the output 115. Instead of a linear functional relationship, as is usually present, it is thus possible to implement any functional relationships. In particular, plateaus used as limit values can be provided, or nonlinear, quadratic, exponential or logarithmic functional relationships can be set. In this way, an output value of a sensor that is not linear with respect to the physical parameter measured by the sensor can be linearized.

It is preferable to couple the programmable recomputing unit with the microcontroller 121 in such a way that the functional relationship can be set via the microcontroller 121 and thus via the gateway 20 and from the higher-level data network.

According to the invention, the signals applied by a functional electronics module 10 at the input 111 and/or emitted at the output 115, which are in digital form on the digital transmission section 113 and which can be processed by the microcontroller 121 within the communication module 120, are detected for the determination of an expected service life of the functional electronics module 10 and/or of an apparatus connected to the input 111 or to the output 115. This is based on the idea that, in the case of a corresponding consideration of the signals at the input or output 111, 115, respectively, valuable information is gained on the expected service life, which can be evaluated by the functional electronics module 10 or transmitted from the functional electronics module 10 to the gateway 20 for evaluation (see FIGS. 1 to 3) and evaluated there. In FIGS. 4 to 7, examples are presented below in which a functional electronics module 10 is used for the estimation of the service life of a connected apparatus.

In a first example, a galvanically separating switch or relay is considered as a functional electronics module 10, and with it a connected apparatus can be switched on or off depending on a level of a digital input. In terms of mode of operation, such a galvanically separating relay is in principle also a signal converter 10a, since a signal is transmitted at an input 111 (for example, a digital signal with logic zero and logic one corresponding to 0 and 5 volt) into a switching signal for switching an apparatus at mains voltage.

In order to perform service life monitoring according to the invention, the functional electronics module 10 has, at the output 115, a possibility for the time-dependent current measurement. As apparatus at the output 115, an electromagnetically actuated valve, referred to as a magnetic valve is provided, which opens when a voltage is emitted at output 115 and closes when there is no voltage at the output 115.

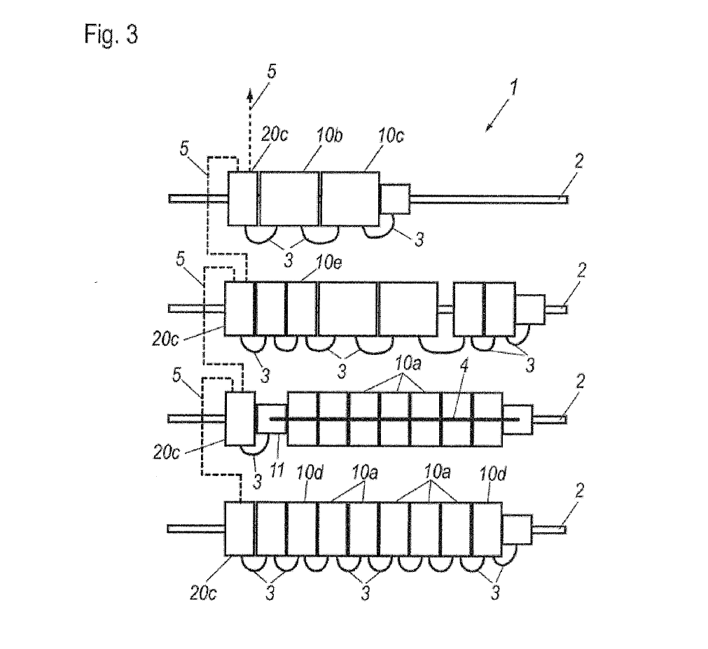

In FIG. 5, as an example, a time dependency of the current course produced in the switch-on process at output 115 is represented as curve 30. The value of the current I is indicated on the vertical axis as a function of time t on the horizontal axis. At time t=0, the output 115 of the functional electronic module 10 is switched by a corresponding setting of the input 111. Due to the inductive load represented by the connected valve, the current for times t>0 at first rises monotonically. Next it passes through a local maximum at time t=t₁ and then it decreases again until time t=t₂ and subsequently it increases again monotonically to the nominal value Iₙ. The reversal of the increase of the current I at time t=t₁ and the renewed increase until time t=t₂ can be associated with movement phases of an armature within the magnetic valve. At time t=t₁, the armature is moving, while time t=t₂ corresponds to the striking of the armature in the opened position of the magnetic valve.

The curve of the current I as a function of time makes it possible to draw conclusions as to the correct operation of the magnetic valve. In particular, a disturbance in the mode of operation is reflected in a shift of times t₁ and t₂. Such a disturbance makes it possible to conclude that there are wear phenomena within the valve, which in turn indicates an end of the service life and which should prompt, starting at a certain point in time, the replacement of the magnetic valve before a disturbance has actually occurred.

The current course is measured by the functional electronics module 10 such as during each switching process of the magnetic valve, and the characteristic times t₁ and/or t₂ are determined. The times can be determined and also evaluated within the microcontroller 121 of the functional electronics module 10. For example, limit values for maximum tolerable times t₁ and t₂ can be stored, and, if they are exceeded, a corresponding warning message is emitted via the first interface 123a/b. In an alternative design, the measured current course according to FIG. 5 can be transmitted via the interface 123a/b to a connected gateway 20 to perform the evaluation of the current course and the comparison with a stored limit value within the gateway 20. It is advantageous that, in a larger system, in which several such functional electronics modules 10 that control the magnetic valves are present, the evaluation apparatus only has to be provided once in the gateway 20.

It is also possible to mix the two designs, for example, so that an evaluation of the measured current for the determination of times t₁ and t₂, takes place within each functional electronics module 10 wherein, via the interface 123a, 123b, the determined times t₁, t₂ are transmitted for further evaluation to the gateway 20.

In a alternative of this design, it is possible to determine other measurement variables within an installation and to determine a value for a service life or an imminent end of a life cycle on the basis of several measured values. In the example shown in FIG. 5, the time dependency of the current course is basically dependent on the wear of the magnetic valve, but it can also be influenced by other parameters. In a viscous medium which is handled by the magnetic valve, it is possible, for example, that a change in the temperature and thus of the viscosity in the medium leads to a changed opening and/or closing behavior. Based on this, it is possible to provide that the limit values for times t₁ and t₂ are stored in a temperature-dependent manner, and a measured temperature of the medium in the area of the magnetic valve is also taken into consideration in the evaluation of times t₁, t₂. In such a case, it is advantageous to perform an evaluation at least partially in the gateway 20 which is coupled to the functional electronics module 10 which controls the magnetic valve and also to an additional functional electronics module, for example, a measurement amplifier, which evaluates a temperature sensor by which the temperature of the medium is determined.

The example reproduced in FIG. 5 related to a digitally operating magnetic valve which can assume only the states “opened” and “closed.” In another embodiment, the service life of apparatuses that are controlled in a continuous or nearly continuous manner with an analog signal can also be determined.

An example of such an apparatus is a proportional valve for shutting off a line with a large conducting cross section whose shut-off slide can be moved continuously between a completely open and a completely closed position. If such a proportional valve is controlled via a functional electronics module 10 designed as a signal converter 10a, it is possible to provide that, over the entire service life of the proportional valve, the actuation distance travelled by the slide is detected and added up. The service life of such a proportional valve is typically determined on the basis of the distance traveled by the slide, since the wear of bearings and guides of the slide is a crucial factor for the service life.

In order to determine the distance that has been traveled, the absolute value of changes of the signal at the output 115 is continuously integrated. This integrated value represents a measure of the use of the proportional valve that has occurred up to that time and can be compared, similar to the embodiment described above, with limit values in order to generate a warning signal which indicates that the lifetime of the proportional valve will end soon. Instead of a warning signal, it is also possible to provide for continuously emitting a use value which indicates the percentage of an expected service life that has been reached to that point.

In such apparatus, in which an input signal leads to a position change, for example, of a slide, an actual value detection is frequently also provided, in order to have available feedback concerning proper operation of the apparatus. This signal can be received and evaluated by another functional electronics module 10. A comparison of the control signal of the apparatus and of the actual value signal of the apparatus immediately shows an incorrect operation. However, it is also possible to provide for considering the temporal response behavior of the apparatus. In that case, a determination is made, for example, of how rapidly a target value to be assumed is in fact reached by the actual value. Here too, limit values can be provided, or it is possible to emit a warning signal when a change in the temporal behavior occurs.

In the case of the values mentioned above, for example, times t₁ and t₂ from FIG. 5, it is also possible to monitor the temporal change of these parameters in addition to a limit value monitoring. Thus, for example, a warning signal can be emitted if the measured values over time differ by more than a certain percentage from the initial value. It is preferable to store, in the functional electronics module 10 and/or in the gateway 20, a history in which measured values are recorded at regular time intervals, in order to be able to retroactively evaluate a behavior of an apparatus and in order to adapt limit values for future cases.

In another embodiment, a vibration sensor, for example, a solid-borne sound sensor is coupled to a mechanical installation component. The sensor is connected to a functional electronics module designed as a signal converter. If the sensor signal received by the signal converter is above a predetermined level, this indicates wear of the mechanical installation component enabling one to conclude that damage to the bearing will occur soon. In the context of the application, an apparatus connected to the functional electronics module is then understood to mean the combination of the mechanical installation components and the sensor.

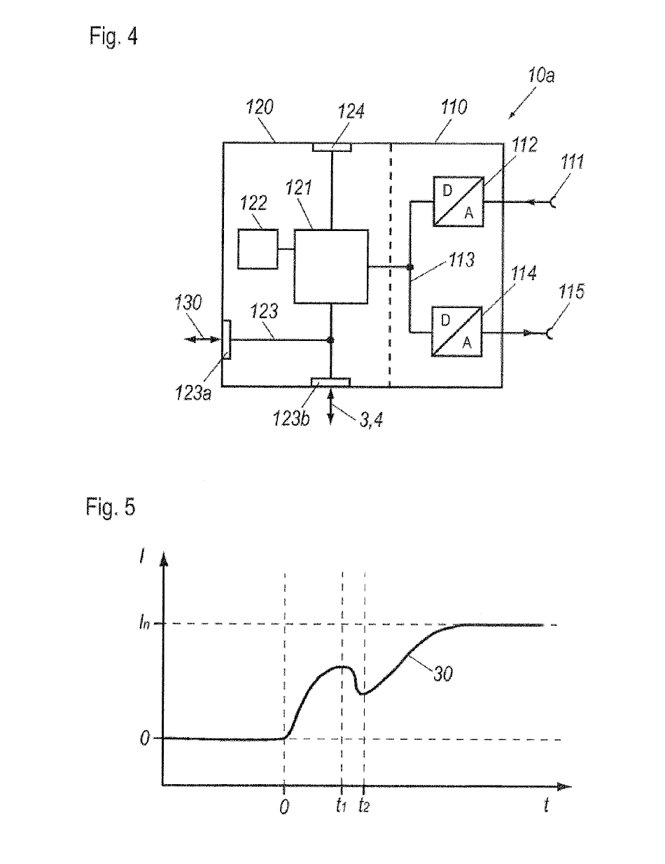

In FIG. 6, the construction of a current supply unit 10b, as an additional example of a functional electronics module 10, is represented in greater detail in the form of a block diagram.

Again, the functional electronics module 10 can be divided into two units, a functional unit 110 and a communication module 120. In this case, the functional unit 110 includes a power supply unit 116 which applies a low voltage of 24 V, for example, to two outputs 115 for the power supply of other connected functional modules 10. The communication module 120 corresponds substantially to the communication module described in the first embodiment of FIG. 3.

The power supply unit 116 has a voltage output 117 which is connected to an analog input of the microcontroller 121. Via the voltage output 117, the output voltage U applied at the outputs 115 can be measured. In addition, a current measurement sensor 118 is provided in the functional unit 110 which is used for the determination of an output current I at the output 115 and which is also connected to an analog input of the microcontroller 121. The current measurement sensor 118 can be implemented, for example, by a Hall sensor or a shunt. Moreover, on the power supply unit 116, a temperature sensor 119 is provided, which is also read by the microcontroller 121. The temperature sensor 119 is used for the determination of an operating temperature T of the power supply unit 116 and is preferably in thermal contact with a power semiconductor or with a cooling body connected thereto and/or with (bulk) electrolyte capacitors of the power supply unit 116 connected thereto.

Via the first interface 123, the operating parameters thus determined, namely the output voltage U, the output current I and the operating temperature T of the power supply unit 116, can be read in by the gateway 20 and seen in the higher level data network to which the gateway 20 is connected.

In one design of the current supply unit 10b, it is possible to calculate, based on these operating parameters, a current state of wear of the power supply unit 116 and to determine therefrom the expected service life of the power supply unit 116 and thus of the functional electronics module 10. The influence of the operating parameters on the service life can be stored, in the form of empirical data obtained individually for this type of functional electronics module 10, in the memory 122 of the communication module 120. As explained above in connection with FIG. 5, an evaluation of the measured operating parameters of the power supply unit 116 can occur in the functional electronics module 10 and also within the gateway 20.

For the determination of the expected service life of a power supply unit 116, the current I supplied by the power supply unit is particularly relevant. The previous wear which a power supply unit has experienced and which indicates the percentage of the expected service life that that has already passed, can be obtained in a first approximation from an integration of the current supplied, that is to say of the overall charge quantity supplied so far. However, the current level does not necessarily enter into the wear that a power supply unit experiences in a linear fashion. Higher currents supplied, for example, lead to more heating of a power supply unit, which in turn has a negative effect on the service life. This can be taken into consideration, for example, by also taking into account the measured temperature T. It is also possible to compute the measured value of the current I first with a nonlinear weighting function, for example, to square it or to compute it with a higher power function or power series or an exponential function, and then to integrate the value obtained.

The service life of certain apparatuses supplied by the power supply unit 116 is also dependent on the current flow that has taken place. For such apparatuses, the integrated current, preferably after the use of a predetermined weighting function, can be used as a measure for the calculation of a still expected service life of the apparatus.

In view of the service life of the power supply unit 116, smoothing capacitors used in the primary and/or in the secondary circuit are particularly critical components. For the evaluation of a service life, an integrated measurement of parameters of such capacitors is therefore advantageous.

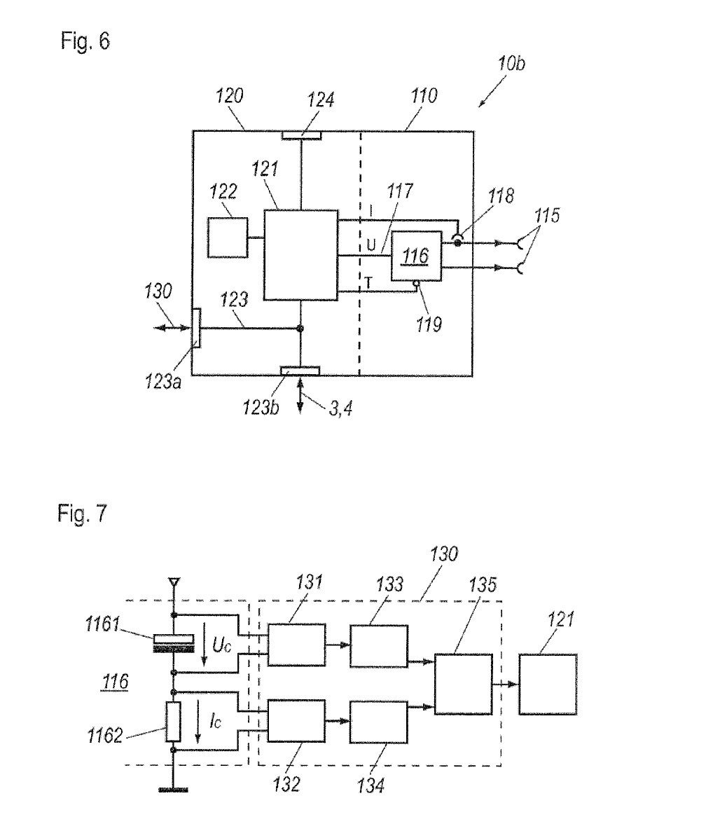

In FIG. 7, an analysis unit 130 is shown, which can be integrated into the current supply unit 10b and which determines the properties of a smoothing capacitor 1161 of the power supply unit 116.

The analysis unit 130 can measure a capacitance C and an equivalent series resistance ESR of the capacitor 1161 during operation. For this purpose, the voltage U_{C} which decreases through the capacitor 1161 can be tapped and supplied to the analysis unit 130. Moreover, a current measurement resistor 1162 is connected in series connection with the capacitor 1161 in the power supply unit 116 by which the current I_{c} flowing through the capacitor 1161 can be measured.

The tapped potentials are supplied, after filtering in filters 131 and 132 implemented as passive and/or digital filters and optionally after amplification in a differential amplifier 133 or 134, to an analog/digital converter with two inputs 135. The filters 131, 132 are preferably narrow-band bandpass filters with a pass frequency at a switching frequency of the power supply unit 116. The output of the analog/digital converter 135 is evaluated by the microcontroller 121.

Via the circuit represented, the height of a ripple voltage applied at the capacitor 1161 is in relation to the height of the current amplitude measured at the current measurement resistor 1162, and from this a value is determined for the equivalent series resistance (ESR) of the capacitor 1161. In the process, effective values and/or amplitude values of current or voltage, respectively, can be used. From a time course of the charging and discharging process at the capacitor 1161, in connection with the measured current course at the current measurement resistor 1162, a value for the capacitance of the capacitor 1161 can also be measured.

In particular, the measured equivalent series resistance ESR and the value of the capacitance C are to a large extent dependent on aging. If the equivalent series resistance ESR exceeds a predetermined limit value, this suggests that the end of the service life of the capacitor 1161 is near. Here too, a comparison with an absolute limit value, with a relative limit value (compared to a value of the series resistance at the time of the first startup of the current supply unit 10b) can occur. Alternatively, it is conceivable to consider a rate of change of one of the parameters (ESR; C) and for an accelerating change to occur as a prompt for emitting a corresponding warning signal, which indicates a possibly imminent end of the service life.

Since the measured properties, the equivalent series resistance ESR and/or the capacitance C of the capacitor 1161 are to a great extent temperature-dependent, temperature compensation is beneficial. In such temperature compensation, a temperature T measured within the power supply unit 116, preferably in the area of the capacitor 1161, is taken into account in considering the measured properties (ESR, C).

For this purpose, on the one hand, the predetermined limit values can be specified in a temperature-dependent manner. Alternatively, it is possible to recompute the measured parameters on the basis of empirically determined functional relationships or tables to values at a standard temperature and to specify the limit values for the standard temperature.

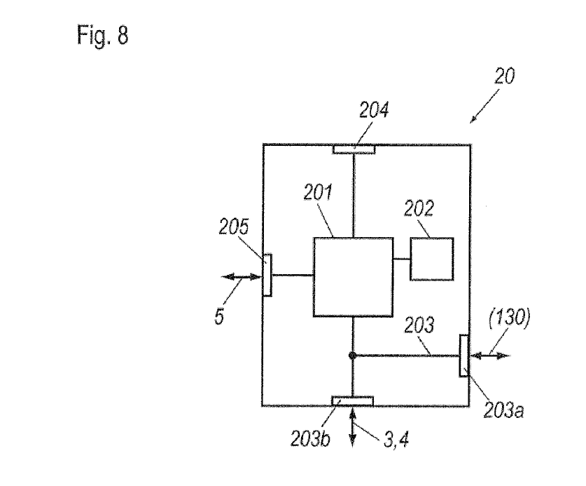

FIG. 8 shows the construction of a gateway 20 in a block diagram. A central component of the gateway 20 is a microcontroller 201 which is connected with an optional external memory 202. The microcontroller 201 has a first interface 203 which at the gateway 20 is designed so that it corresponds to the interfaces 123a and 123b of the communication module 120 as first internal interface 203a and/or bus-capable interface 203b. The bus-capable interface 203b can be present in multiple embodiments in order to supply various strings of functional modules 10 with separate local bus lines 3, 4, as represented in FIG. 1.

In addition, a service interface 204 is connected with the microcontroller 201 and is used for the connection of the microcontroller 201 to a laptop of a service technician on site at the switch cabinet 1 in order to update the gateway 20 and/or to establish a defect diagnosis.

In addition, a second interface 205 is provided at the gateway 20 through which the gateway 20 can be coupled via the network line 5 to the higher-level data network. Preferably, the second interface is an Ethernet interface. It is possible to provide multiple interfaces 205 arranged on the gateway 20 which are connected to one another via an integrated switch. Such a gateway 20 is shown in the embodiment example of FIG. 2, for example.

The gateway 20 applies configuration parameters of connected functional electronics modules 10 in the additional memory 202. Such configuration parameters relate to the functional relationship between the input and the output of a signal converter 10b which is stored in a programmable recomputing unit. If the signal converter 10b is replaced due to a defect, a newly inserted signal converter 10b is recognized by the gateway, and its programmable recomputing unit is set up accordingly so that the desired functional relationship in the case of the new signal converter 10b is immediately converted without an intervention via the high-level data network.

In another alternative embodiment of the gateway 20, the latter can be integrated in a functional electronics module 10. A connection with the communication module 120 of the functional electronics module 10 occurs via the respective first interface 123a or 203a. Optionally, the bus-capable first interface 203b of the gateway 20 is present, and it can be led outward at the functional electronics module 10 to connect other functional electronics modules 10 which do not include an integrated gateway 20, via their bus-capable first interface 123b.

While the preferred forms and embodiments of the invention have been illustrated and described, it will be apparent to those of ordinary skill in the art that various changes and modifications may be made without deviating from the inventive concepts set forth above.

1-22. (canceled)

23. An operating method for a functional electronics module for autonomous signal processing, which is suitable for assembly on a mounting rail and includes at least one input and at least one output, comprising the steps of receiving a signal at the at least one input;
processing the signal autonomously;
emitting a signal at the at least one output;
detecting the signal applied at the input and/or emitted at the output and emitting the signal in digital form via a first interface through a communication module of the functional electronics module; and
determining a service life of an installation component on the basis of at least one of the signal applied at the input, the signal emitted at the output, measured operating parameters of the functional electronics module.

24. A method as defined in claim 23, wherein the service life of the functional electronics module is determined.

25. A method as defined in claim 23, wherein the service life of an apparatus connected to at least one of the input and the output (115) of the functional electronics module is determined.

26. A method as defined in claim 23, wherein the service life is determined within the functional electronics module (10).

27. A method as defined in claim 25, wherein the detected data signals are transmitted via the first interface to a higher-level gateway and the service life is determined within the gateway.

28. A method as defined in claim 23, wherein one of the signal applied at the input, the signal emitted at the output, and an absolute value of a change of one of these signals is integrated, and further wherein wear that has occurred from the value of the integrated signal in order to determine the service life of the installation component.

29. A method as defined in claim 23, wherein one of an absolute and relative change of the one of the signal applied at the input and of the signal emitted at the output is detected for determining the service life.

30. A functional electronics module for assembly on a mounting rail and having at least one input and at least one output for autonomously processing a signal applied to the least one input and autonomously emitting a signal applied to the at least one output, comprising
a communication module for detecting signals applied at the input and/or emitted at the output and emitting the signals in digital form via a first interface, wherein the functional electronics module detects at least one of the signals applied at the input, signals emitted at the output, and measured operating parameters of the functional electronics module to determine a service life of at least one of the functional electronics module an apparatus connected to the input, or to the output.

31. A functional electronics module as defined in claim 30, wherein the operating parameters comprise at least one of a temperature measured within the functional electronics module, a voltage measured within the functional electronics module, and a current flow within the functional electronics module.

32. A functional electronics module as defined in claim 31, wherein operating parameters of the functional electronics module are emitted in digital form via the first interface.

33. A functional electronics module as defined in claim 32, wherein the first interface is a bus interface.

34. A functional electronics module as defined in claim 33, and further comprising a signal converter in which a signal applied at the input is represented at the output, wherein one of a signal emitted at the output and an absolute value of a signal change is integrated, and further wherein wear that has occurred and the service life of the connected apparatus are determined from the value of the integrated signal.

35. A functional electronics module as defined in claim 34, and further comprising a current supply unit wherein a low voltage is provided at the output for the current supply of components of a switch cabinet.

36. A functional electronics module as defined in claim 35, wherein a current flow at the output is integrated, and further wherein wear that has occurred and the service life of one of the functional electronics module and of the connected apparatus are determined from the value of the integrated current flow.

37. A functional electronics module as defined in claim 36, and further comprising at least one smoothing capacitor, wherein at least one of a capacitance and a series resistance of the smoothing capacitor is determined based on the operating parameters of the functional electronics module and the service life of the functional electronics module is determined based on at least one of the capacitance and the series resistance.

38. A functional electronics module as defined in claim 37, wherein the service life of at least one of the functional electronics module and the connected apparatus is determined within the functional electronics module.

39. A system including at least one functional electronics module as defined in claim 8 and a gateway comprising a first interface which is connected to the first interface of the communication module, wherein the gateway is programmed to determine, from data transmitted by the functional electronics module, at least one of the service life of the functional electronics module and an apparatus connected via the first interface to said functional electronics module.

40. A system as defined in claim 39, comprising multiple functional electronics modules connected with the gateway, wherein the gateway receives data from the multiple functional electronics modules, combines the data, and determines the service life of the apparatus.

41. A system as defined in claim 40, wherein the gateway comprises a second interface for connection of a network line to a higher-level data network.

42. A system as defined in claim 41, wherein the gateway is integrated in a functional electronics module, and further wherein a connection occurs via internal first interfaces.

43. A system as defined in claim 42, wherein the integrated gateway comprises a bus-capable first interface for connection to other functional electronics modules.

44. A system as defined in claim 43, wherein the gateway comprises a separate housing for assembly on a mounting rail.
